(19) United States
(12) Patent Application Publication
(10) Pub. No.: US 2026/0301784 A1
(43) Pub. Date: Oct. 1, 2026

(54) SENSE AMPLIFYING CIRCUIT AND MEMORY DEVICE INCLUDING THE SAME

(71) Applicant: SK hynix Inc., Gyeonggi-do (KR)

(72) Inventor: Ju Hyun PARK, Gyeonggi-do (KR)

(21) Appl. No.: 19/291,603

(22) Filed: Aug. 6, 2025

(30) Foreign Application Priority Data
Mar. 26, 2025 (KR) 10-2025-0038562

(51) Int. Cl. G11C 7/06; G11C 7/08; G11C 7/12

(52) U.S. Cl. CPC G11C 7/065; G11C 7/08; G11C 7/12

(57) ABSTRACT

A sense amplifying circuit includes a replica circuit including one or more active resistors coupled in series between a ground voltage node and a first node; a current control circuit configured to supply a keeper current to a sensing node coupled to at least one memory cell when a sensing enable signal is activated, and to control an amount of the keeper current based on a voltage level of the first node; and a sensing circuit configured to sense and output a voltage at the sensing node.

### CROSS-REFERENCE TO RELATED APPLICATIONS

The present application claims the benefit of Korean Patent Application No. 10-2025-0038562, filed on Mar 26, 2025, which is incorporated herein by reference in its entirety.

### BACKGROUND

### Field

Various embodiments of the present disclosure relate to a semiconductor design technology, and more particularly, to a sense amplifying circuit of a read-only memory (ROM) device.

### Description of the Related Art

A semiconductor device, particularly a memory device, may be broadly classified into a volatile memory device and a nonvolatile memory device. The nonvolatile memory device may retain stored data even when power supply is interrupted, although it typically has relatively slower read and write speeds. Therefore, the nonvolatile memory device may be used to store data that must be preserved regardless of power supply status.

Among nonvolatile memory devices, a read-only memory (ROM) may be implemented as a mask read-only memory (MROM), a programmable read-only memory (PROM), a one-time programmable (OTP) ROM, an erasable programmable read-only memory (EPROM), and/or an electrically erasable programmable read-only memory (EEPROM). As technology scaling has progressed and the area of memory devices has been reduced, various methods have been studied to accurately sense and read the data stored in the ROM.

### SUMMARY

Embodiments of the present disclosure are directed to a sense amplifying circuit capable of accurately sensing data of read-only memory (ROM) cells, and a memory device including the same.

In accordance with an embodiment of the present disclosure, a sense amplifying circuit includes a replica circuit including one or more active resistors coupled in series between a ground voltage node and a first node; a current control circuit configured to supply a keeper current to a sensing node coupled to at least one memory cell when a sensing enable signal is activated, and to control an amount of the keeper current based on a voltage level of the first node; and a sensing circuit configured to sense and output a voltage at the sensing node.

In accordance with an embodiment of the present disclosure, a memory device includes a memory cell array having a plurality of memory cells arranged between a plurality of word lines and a plurality of bit lines; a column control circuit configured to select one of the plurality of bit lines based on a column address and connect the selected bit line to a sensing node; and a sense amplifying circuit including one or more active resistors, which are coupled in series between a ground voltage node and a first node and configured to simulate characteristics of the memory cells, output read data by sensing a voltage at the sensing node and control an amount of a keeper current supplied to the sensing node based on a voltage level of the first node.

According to embodiments of the present disclosure, the memory device may perform an accurate sensing operation even in an SF (slow-fast) corner where a conflict (or fighting) between the existing cell current and the keeper current becomes severe, thereby minimizing the read failure and improving the reliability.

According to embodiments of the present disclosure, the memory device may maximize the layout efficiency by overcoming the limitation in using high-resistance wiring materials, which has been restricted due to the conflict between the existing cell current and the keeper current.

These and other features and advantages of the embodiments of the present disclosure will become apparent to those skilled in the art from the following detailed description in conjunction with the following drawings.

### BRIEF DESCRIPTION OF THE DRAWINGS

FIG. 1 is a block diagram illustrating a memory device according to an embodiment of the present disclosure.

FIG. 2 is a detailed configuration diagram illustrating the memory device of FIG. 1.

FIGS. 3A and 3B are equivalent circuit diagrams illustrating ROM memory cells storing data “0” and data “1”, respectively.

FIG. 4 is a detailed circuit diagram illustrating one of sense amplifiers of a sense amplifying circuit according to an embodiment of the present disclosure.

FIG. 5 is a circuit diagram for describing a connection between a keeper circuit and a sensing circuit of FIG. 4.

FIGS. 6A and 6B are a timing diagram and a circuit diagram for describing a sensing operation of the sense amplifier of FIG. 4.

FIG. 7 is a detailed circuit diagram illustrating one of sense amplifiers of a sense amplifying circuit according to another embodiment of the present disclosure.

FIGS. 8A and 8B are a timing diagram and a circuit diagram for describing a sensing operation of the sense amplifier of FIG. 7.

### DETAILED DESCRIPTION

Various embodiments of the present disclosure will be described below in more detail with reference to the accompanying drawings. The embodiments of the present disclosure may, however, be in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

It will be understood that when an element is referred to as being “coupled” or “coupled” to another element, it may mean that the two are directly coupled or the two are electrically coupled to each other with another circuit intervening therebetween. It will be further understood that the terms “comprise”, “include”, “have”, etc. when used in this specification, specify the presence of stated features, numbers, steps, operations, elements, components, and/or combinations of them but do not preclude the presence or addition of one or more other features, numbers, steps, operations, elements, components, and/or combinations thereof. In the present disclosure, the singular forms are intended to include the plural forms as well, unless the context clearly indicates otherwise.

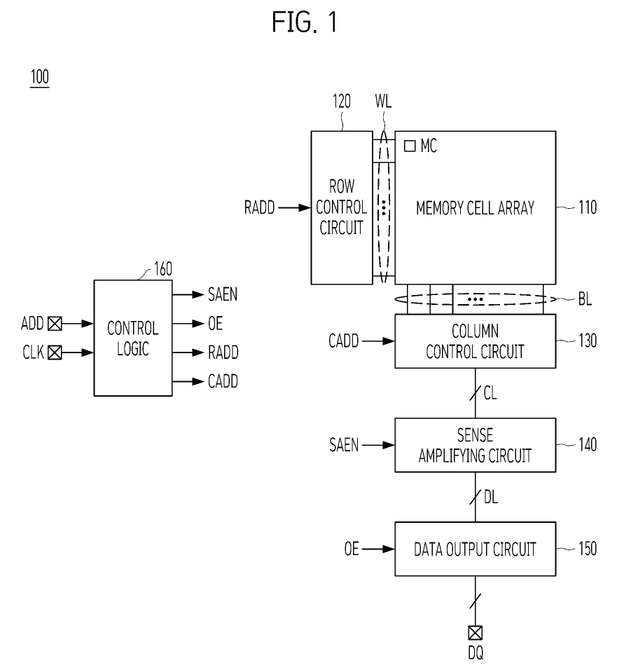

FIG. 1 is a block diagram illustrating a memory device 100 according to an embodiment of the present disclosure.

Referring to FIG. 1, the memory device 100 may be a storage device based on a semiconductor element. In an embodiment of the present disclosure, the memory device 100 may be implemented with a nonvolatile memory device capable of retaining stored data even when power is not supplied. Preferably, the memory device 100 may be implemented with a read-only memory (ROM). The memory device 100 may output data DQ in response to a command/address signal C/A received from an external device (e.g., a memory controller).

More specifically, the memory device 100 may include a memory cell array 110, a row control circuit 120, a column control circuit 130, a sense amplifying circuit 140, a data output circuit 150, and a control logic 160.

The memory cell array 110 may refer to a region in the memory device 100 where data is stored, and may include a plurality of memory cells MC for storing data. The plurality of memory cells MC may be coupled between a plurality of word lines WL and a plurality of bit lines BL, and may be arranged in an array type. The memory cell array 110 may be coupled to the row control circuit 120 through the plurality of word lines WL, and may be coupled to the column control circuit 130 through the plurality of bit lines BL. The plurality of word lines WL may extend in a first direction (e.g., a row direction) and sequentially arranged in a second direction (e.g., a column direction). The plurality of bit lines BL may extend in a column direction and are sequentially arranged in a row direction. The plurality of memory cells MC may include ROM cells that permanently retain data once stored.

The control logic 160 may generate control signals for controlling various operations of the memory device 100 based on a clock CLK and an address ADD provided from the external device. For example, the control logic 160 may generate a sensing control signal SAEN for controlling an operation timing of the sense amplifying circuit 140, and an output control signal OE for controlling an operation timing of the data output circuit 150, in synchronization with the clock CLK and in response to the input address ADD. Although in FIG. 1, it is illustrated that the control logic 160 provides only signals for controlling the operations of the sense amplifying circuit 140 and the data output circuit 150, the embodiments of the present disclosure are not limited thereto, and the control logic 160 may additionally provide control signals for controlling each component of the memory device 100. The control logic 160 may also classify the input address ADD, based on the clock CLK, into a row address RADD and a column address CADD. The row address RADD may be an address for selecting one of the plurality of word lines WL, and the column address CADD may be an address for selecting bit lines BL on which a read operation is to be performed among the plurality of bit lines. Each of the row address RADD and the column address CADD may be multi-bit.

The row control circuit 120 may select one of the plurality of word lines WL coupled to the memory cell array 110. The row control circuit 120 may decode the row address RADD received from the control logic 160 to select one word line corresponding to the row address RADD and activate the selected word line.

The column control circuit 130 may select a predetermined number of bit lines among the plurality of bit lines BL coupled to the memory cell array 110. For example, the column control circuit 130 may decode the column address CADD received from the control logic 160 to simultaneously select 128 bit lines. Accordingly, data (hereinafter referred to as "first data") composed of 128 bits may be output from the selected bit lines. The first data may be transferred to column lines CL.

The sense amplifying circuit 140 may be coupled to the column control circuit 130 through the column lines CL and coupled to the data output circuit 150 through data lines DL. The sense amplifying circuit 140 may sense and amplify the first data transferred through the column lines CL and output the sensed first data to the data lines DL, according to the sensing control signal SAEN provided from the control logic 160.

The data output circuit 150 may receive data (hereinafter referred to as "second data") transferred through the data lines DL from the sense amplifying circuit 140 to output output data DQ to the external device.

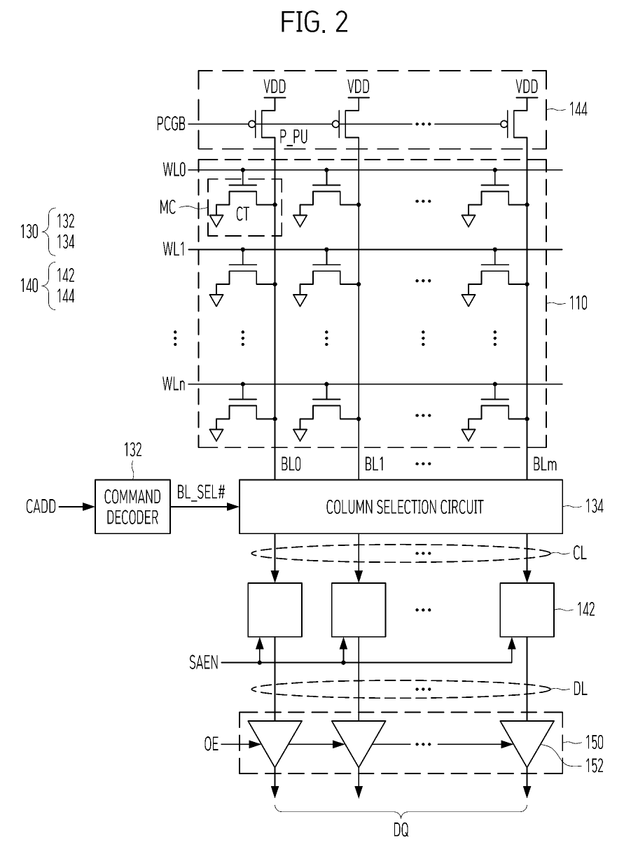

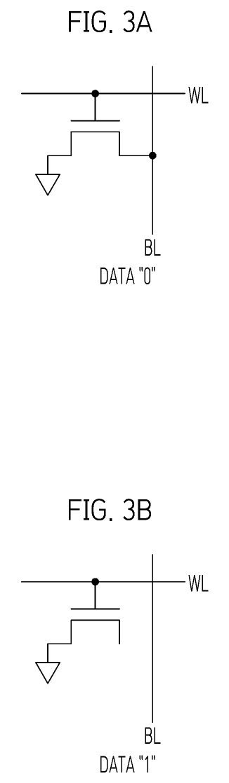

FIG. 2 is a detailed configuration diagram illustrating the memory device 100 of FIG. 1. FIGS. 3A and 3B are equivalent circuit diagrams illustrating ROM memory cells storing data “0” and data “1”, respectively.

Referring to FIG. 2, components of the memory device 100 related to data output are illustrated.

The memory cell array 110 may include the plurality of memory cells MC arranged in an array type, coupled between a plurality of word lines WL0 to WLn, where n is an integer equal to or greater than 1, and a plurality of bit lines BL0 to BLm, where m is an integer equal to or greater than 1. The memory cells MC may be configured as ROM cells each consisting of a single cell transistor CT. Each cell transistor CT may be coupled between a ground voltage and a corresponding bit line, and have a gate coupled to a corresponding word line.

Each of the memory cells MC may be programmed to store either data "0" or data "1" depending on whether the memory cell MC is electrically coupled to a bit line. That is, during the manufacturing process, data having a fixed logic level may be programmed in the memory cell MC in accordance with a user's requirements. For example, when an electrical connection between the memory cell MC and the bit line is determined by the presence or absence of a contact hole formed through a contact process, the memory cell MC and the bit line are electrically coupled when the contact hole is formed (as shown in FIG. 3A), resulting in the bit line being discharged, and thus the data "0" may be stored in the memory cell MC. On the other hand, when no contact hole is formed and the memory cell MC is not coupled to the bit line (as shown in FIG. 3B), since discharging through the bit line does not occur, the data "1" may be stored in the memory cell MC. Depending on an embodiment, the memory cell MC may also be programmed to store data "0" or data "1" based on the presence or absence of the cell transistor CT. For example, when the cell transistor CT is present, the data "0" may be stored in the memory cell MC, and when the cell transistor CT is absent, the data "1" may be stored in the memory cell MC.

The column control circuit 130 may include a column decoder 132 and a column selection circuit 134. The column decoder 132 may decode the column address CADD to activate one of a plurality of column selection signals BL_SEL#, where # represents plural numbers. The column selection circuit 134 may select a predetermined number of bit lines among the bit lines BL0 to BLm according to the column selection signals BL_SEL# and map the selected bit lines to the column lines CL. For example, when 1024 bit lines BL0 to BL1023 and 128 column lines CL0 to CL127 are arranged, the column selection circuit 134 may map 128 bit lines among the 1024 bit lines BL0 to BL1023 to the 128 column lines CL0 to CL127 according to the first to eighth column selection signals BL_SEL0 to BL_SEL7.

The sense amplifying circuit 140 may include a plurality of sense amplifiers 142 respectively corresponding to the column lines CL, and a precharge circuit 144. Each of the sense amplifiers 142 may sense and amplify a voltage change on a corresponding one of the column lines CL according to the sensing control signal SAEN, and may output the sensed voltage to a corresponding one of the data lines DL. The precharge circuit 144 may precharge the bit lines BL0 to BLm to a power supply voltage level during a read operation. The precharge circuit 144 may include a plurality of precharge transistors P_PU each of which is coupled between a power supply voltage node and a corresponding one of the bit lines BL0 to BLm, and has a gate configured to receive a precharge signal PCGB. The precharge transistors P_PU may be implemented with PMOS transistors, in which case the precharge signal PCGB may be activated to a logic low level. During a read operation, after all the bit lines BL0 to BLm are precharged by the precharge circuit 144, a sensing operation may be performed. Depending on embodiment, the precharge signal PCGB may be generated based on the sensing control signal SAEN.

The data output circuit 150 may include a plurality of output drivers 152 for respectively driving the data lines DL. The output drivers 152 may drive the second data transferred through the data lines DL and output the second data as the output data DQ to the external device. According to an embodiment, the output drivers 152 may invert the second data and output the inverted data as the output data DQ.

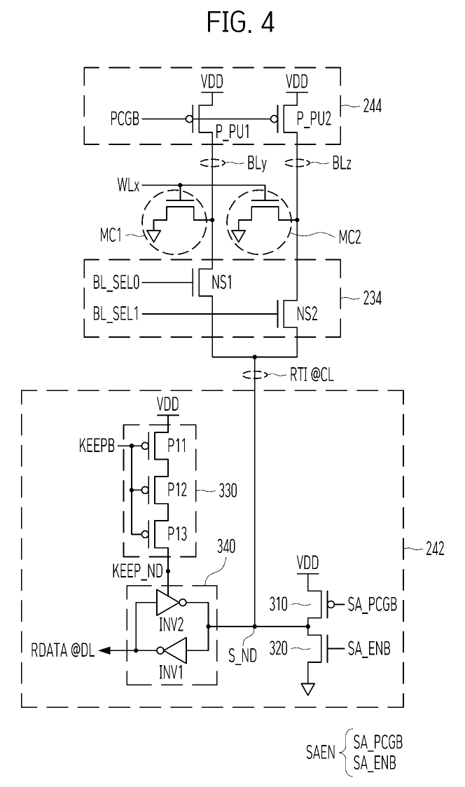

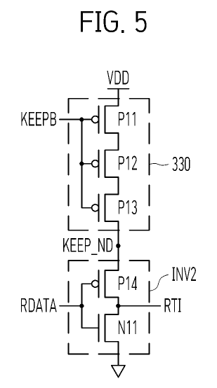

FIG. 4 is a detailed circuit diagram illustrating one of sense amplifiers 242 of the sense amplifying circuit 140 according to an embodiment of the present disclosure. FIG. 5 is a circuit diagram for describing a connection between a keeper circuit 330 and a sensing circuit 340 of FIG. 4.

Referring to FIG. 4, for convenience of description, a case is illustrated where the sense amplifier 242 is disposed to sense and amplify data of a first memory cell MC1 coupled between a word line WLx and a first bit line BLy, and a second memory cell MC2 coupled between the word line WLx and a second bit line BLz. A sensing precharge signal SA_PCGB and a sensing enable signal SA_ENB shown in FIG. 4 may be included in the sensing control signal SAEN of FIG. 1. The sensing precharge signal SA_PCGB and the sensing enable signal SA_ENB are both activated to a logic low level. A keeper signal KEEPB in FIG. 4 is a signal maintaining a logic low level and, depending on embodiments, may be fixed to a ground voltage level.

A precharge circuit 244 may include a first precharge transistor P_PU1 that is coupled between a power supply voltage node and the first bit line BLy, and has a gate receiving the precharge signal PCGB, and a second precharge transistor P_PU2 that is coupled between the power supply voltage node and the second bit line BLz, has a gate receiving the precharge signal PCGB. The first precharge transistor P_PU1 and the second precharge transistor P_PU2 may be implemented with PMOS transistors.

The column selection circuit 234 includes a first connection transistor NS1 that connects the first bit line BLy to a column line CL according to a first column selection signal BL_SEL0, and a second connection transistor NS2 that connects the second bit line BLz to the column line CL according to a second column selection signal BL_SEL1. The first connection transistor NS1 and the second connection transistor NS2 may be implemented with NMOS transistors.

The sense amplifier 242 may sense and amplify the first data RTI at the column line CL and output the second data RDATA to the data line DL. More specifically, the sense amplifier 242 may include a sensing precharge circuit 310, a sensing enable circuit 320, a keeper circuit 330, and a sensing circuit 340.

The sensing precharge circuit 310 may precharge the sensing node S_ND coupled to the column line CL to a power supply voltage level in response to the sensing precharge signal SA_PCGB. The sensing precharge circuit 310 may include a PMOS transistor which is coupled between the power supply voltage node and the sensing node S_ND, and has a gate receiving the sensing precharge signal SA_PCGB. When the sensing precharge signal SA_PCGB is activated to a logic low level, the sensing precharge circuit 310 may precharge the sensing node S_ND to the power supply voltage level.

The sensing enable circuit 320 may enable or disable the sense amplifier 242 in response to the sensing enable signal SA_ENB. The sensing enable circuit 320 may include an NMOS transistor which is coupled between the sensing node S_ND and a ground voltage node, and has a gate receiving the sensing enable signal SA_ENB. When the sensing enable signal SA_ENB is deactivated to a logic high level, the NMOS transistor may be turned on to discharge the sensing node S_ND to the ground voltage level, thereby disabling the sense amplifier 242.

The keeper circuit 330 may be coupled between the power supply voltage node and a down-voltage node KEEP_ND, and may supply a voltage level dropped from the power supply voltage level to the down-voltage node KEEP_ND. For example, the keeper circuit 330 may include first to third PMOS transistors P11, P12, and P13 which are coupled in series between the power supply voltage node and the down-voltage node KEEP_ND, and each of which has a gate receiving a keeper signal KEEPB fixed to a logic low level. In this case, the keeper circuit 330 may provide the down-voltage node KEEP_ND with a voltage level 3×Vth (threshold voltage) lower than the power supply voltage level.

The sensing circuit 340 may output the second data RDATA to the data line DL by latching a voltage level of a signal (i.e., the first data RTI) at the sensing node S_ND. The sensing circuit 340 may be implemented with an inverter latch coupled between the sensing node S_ND and the data line DL. The inverter latch may include a first inverter INV1 and a second inverter INV2, which are cross-coupled. The first inverter INV1 may be implemented with a PMOS transistor and an NMOS transistor coupled in series between the power supply voltage node and the ground voltage node. In contrast, as illustrated in FIG. 5, the second inverter INV2 may be implemented with a PMOS transistor P14 and an NMOS transistor N11 coupled in series between the down-voltage node KEEP_ND and the ground voltage node. Since the PMOS transistor P14 of the second inverter INV2 receives a voltage level 3×Vth lower than the power supply voltage level, its strength is weakened compared to the PMOS transistor of the first inverter INV1, and accordingly, the second inverter INV2 may have a driving capability lower than that of the first inverter INV1.

Hereinafter, with reference to the drawings, an operation of the sense amplifier 242 of FIG. 4 will be described.

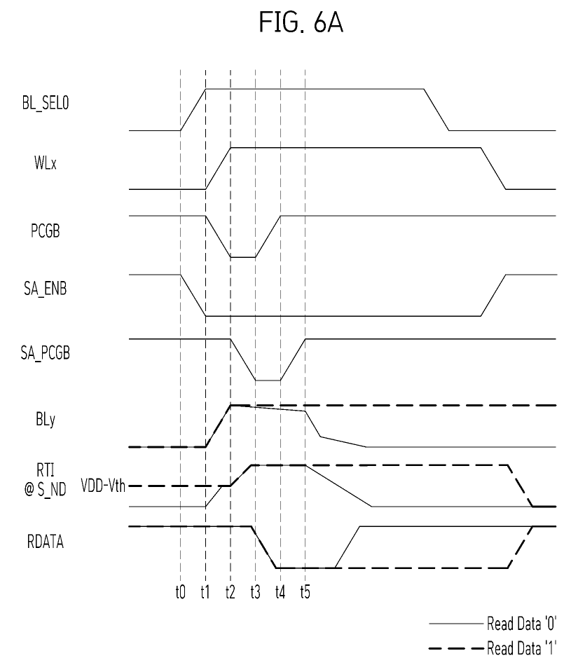

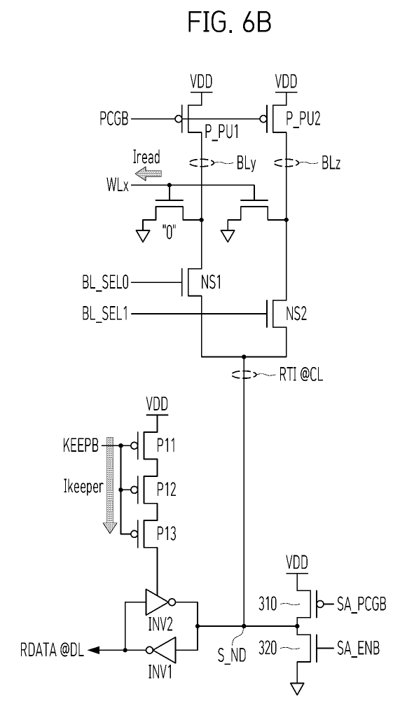

FIGS. 6A and 6B are a timing diagram and a circuit diagram for describing a sensing operation of the sense amplifier 242 of FIG. 4.

Referring to FIG. 6A, prior to time point t0, the sensing enable signal SA_ENB is deactivated to a logic high level. As a result, the sensing enable circuit 320 discharges the sensing node S_ND to the ground voltage level, and the sensing circuit 340 inverts the first data RTI of a logic low level to output the second data RDATA of a logic high level to the data line DL.

At time point t0, the first column selection signal BL_SEL0 is activated to a logic high level, and the sensing enable signal SA_ENB is activated to a logic low level. The first connection transistor NS1 connects the first bit line BLy to the column line CL in response to the first column selection signal BL_SEL0, and the sensing enable circuit 320 enables the sense amplifier 242 from the disabled state according to the sensing enable signal SA_ENB. At this time, the sensing circuit 340 may maintain the second data RDATA at a logic high level.

At time point t1, the precharge signal PCGB is activated to a logic low level, and the word line WLx is activated. The first precharge transistor P_PU1 and the second precharge transistor P_PU2 are activated in response to the precharge signal PCGB, and precharge both the first bit line BLy and the second bit line BLz to the power supply voltage level. In addition, as the word line WLx is selected, a sensing operation for reading data from the first memory cell MC1 may begin. As the first bit line BLy is precharged, the first data RTI at the sensing node S_ND may also be precharged to the power supply voltage level. However, since the first connection transistor NS1 is implemented with an NMOS transistor, the sensing node S_ND is charged only up to a voltage level of (VDD − Vth), not fully to the power supply voltage level, even when the first bit line BLy is precharged. Accordingly, the sensing circuit 340 may maintain the second data RDATA at a logic high level.

At time point t2, as the sensing precharge signal SA_PCGB is activated to a logic low level, the sensing precharge circuit 310 precharges the sensing node S_ND to the power supply voltage level. Accordingly, when a voltage level of the sensing node S_ND sufficiently increases, the sensing circuit 340 may output the second data RDATA at a logic low level to the data line DL by inverting the first data RTI at a logic high level. At this time, when the first memory cell MC1 is not connected to the first bit line Bly, i.e., when the stored data is "1", the first bit line BLy may maintain the power supply voltage level. In contrast, when the first memory cell MC1 is connected to the first bit line Bly, i.e., when the stored data is "0", the voltage level of the first bit line BLy may decrease from the power supply voltage level.

At time point t3, as the precharge signal PCGB is deactivated, the precharge operation on the first bit line BLy is terminated.

At time point t4, as the sensing precharge signal SA_PCGB is deactivated, the precharge operation on the sensing node S_ND is terminated.

At time point t5, the voltage level of the first bit line BLy may vary depending on the data stored in the first memory cell MC1. For example, when the data "1" is stored in the first memory cell MC1, the first bit line BLy may maintain the power supply voltage level, and accordingly, the first data RTI at the sensing node S_ND also remains at a logic high level (dotted line). The sensing circuit 340 may output the second data RDATA of a logic low level to the data line DL, by inverting the first data RTI of a logic high level. That is, the sensing circuit 340 may maintain the second data RDATA at a logic low level. In contrast, when the data "0" is stored in the first memory cell MC1, the first bit line BLy is discharged from the power supply voltage level to the ground voltage level, and accordingly, the sensing node S_ND is also discharged (solid line). Then, the sensing circuit 340 may output the second data RDATA of a logic high level to the data line DL, by inverting the first data RTI at the sensing node S_ND.

When the data "1" is stored in the first memory cell MC1, in order to prevent the sensing node S_ND from failing to maintain the power supply voltage level due to leakage current, the sensing circuit 340 may be implemented with an inverter latch including a feedback inverter (i.e., INV2) so that the sensing node S_ND may maintain the power supply voltage level. However, when the data "0" is stored in the first memory cell MC1, the sensing node S_ND should be discharged to the ground voltage level, but the second inverter INV2 in the inverter latch tries to maintain the sensing node S_ND at the power supply voltage level, thereby disturbing the discharge operation. Therefore, the keeper circuit 330 may be provided to reduce the driving strength of the second inverter INV2. That is, since the keeper circuit 330 provides the second inverter INV2 with a voltage level 3×Vth lower than the power supply voltage level, the second inverter INV2 has weaker driving strength compared to the first inverter INV1, thereby allowing the sensing node S_ND to be discharged to the ground voltage level.

However, as illustrated in FIG. 6B, even when the driving strength of the second inverter INV2 is reduced, a conflict (or a fighting) may occur between a keeper current Ikeeper flowing through the keeper circuit 330 and a cell current Iread flowing through the first memory cell MC1. That is, the keeper current Ikeeper, which tries to maintain the sensing node S_ND at the power supply voltage level, may conflict with the cell current Iread which tries to pull the sensing node S_ND down to the ground voltage level. In particular, in an SF (Slow-Fast) corner in which the driving strength of NMOS transistors becomes weaker and the driving strength of PMOS transistors becomes stronger, the cell current Iread flowing through the cell transistor configured with an NMOS transistor weakens, while the keeper current Ikeeper flowing through the keeper circuit 330 configured with a PMOS transistor becomes stronger. This may cause a read failure due to the conflict between the keeper current Ikeeper and the cell current Iread.

For reference, process corners represent fabrication conditions of NMOS and PMOS transistors that affect device performance and are denoted by FS, FF, TT, SS, and SF. The first character indicates the NMOS corner, and the second character indicates the PMOS corner. The designations S (Slow), T (Typical), and F (Fast) represent increasing a level of a threshold voltage. Therefore, the SF (Slow-Fast) corner may indicate a condition in which the NMOS transistor has a higher threshold voltage and the PMOS transistor has a lower threshold voltage.

In the following embodiment, a sense amplifying circuit capable of preventing the read failure in the SF corner will be described.

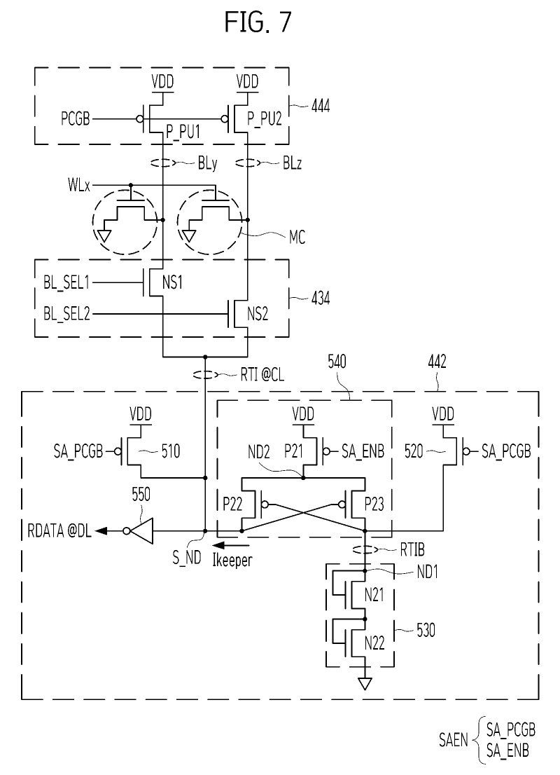

FIG. 7 is a detailed circuit diagram illustrating one of sense amplifiers 442 of the sense amplifying circuit 140 according to another embodiment of the present disclosure.

Referring to FIG. 7, for convenience of description, a case is illustrated in which the sense amplifier 442 is disposed to sense and amplify data of a first memory cell MC1 connected between a word line WLx and a first bit line BLy, and a second memory cell MC2 connected between the word line WLx and a second bit line BLz. A sensing precharge signal SA_PCGB and a sensing enable signal SA_ENB shown in FIG. 7 may be included in the sensing control signal SAEN of FIG. 1. Both the sensing precharge signal SA_PCGB and the sensing enable signal SA_ENB are signals that are activated to a logic low level.

The column selection circuit 434 and the precharge circuit 444 in FIG. 7 may have substantially the same configuration and operation as the column selection circuit 234 and the precharge circuit 244 of FIG. 4.

The sense amplifier 442 may sense and amplify the first data RTI at the column line CL and output the second data RDATA to the data line DL. More specifically, the sense amplifier 442 may include a first sensing precharge circuit 510, a second sensing precharge circuit 520, a replica circuit 530, a current control circuit 540, and a sensing circuit 550.

The first sensing precharge circuit 510 may precharge the sensing node S_ND coupled to the column line CL to a power supply voltage level in response to the sensing precharge signal SA_PCGB. The first sensing precharge circuit 510 may include a PMOS transistor which is coupled between the power supply voltage node and the sensing node S_ND, and has a gate receiving the sensing precharge signal SA_PCGB.

The second sensing precharge circuit 520 may precharge a first node ND1 to the power supply voltage level in response to the sensing precharge signal SA_PCGB. The second sensing precharge circuit 520 may include a PMOS transistor which is coupled between the power supply voltage node and the first node ND1, and has a gate receiving the sensing precharge signal SA_PCGB. The PMOS transistors included in the first and second sensing precharge circuits 510 and 520 may be referred to as sensing precharge transistors.

The replica circuit 530 may include first and second active resistors N21 and N22 coupled in series between a ground voltage node and the first node ND1. The first and second active resistors N21 and N22 may include resistance elements whose resistance values vary depending on process, voltage and temperature (PVT) variation. In an embodiment, the first and second active resistors N21 and N22 may be implemented with diode-connected transistors. However, the embodiments of the present disclosure are not limited thereto, and the first and second active resistors N21 and N22 may be implemented using various elements whose resistance varies with the PVT variation such as diode devices, BJT devices, etc. In an embodiment, the first and second active resistors N21 and N22 may be implemented with NMOS transistors having the same polarity type as that of the cell transistors included in the memory cell. That is, the replica circuit 530 may include one or more active resistors N21 and N22 that simulate the characteristics of the memory cell to drive the first node ND1. During a period in which the sensing precharge signal SA_PCGB is deactivated, a voltage level RTIB of the first node ND1 may be maintained at a voltage level of 2×Vth by the first and second active resistors N21 and N22. In an SF corner where the threshold voltage of the NMOS transistors increases, the voltage level RTIB of the first node ND1 may increase.

The current control circuit 540 may supply a keeper current Ikeeper to the sensing node S_ND when the sensing enable signal SA_ENB is activated, and may control an amount of the keeper current Ikeeper according to the voltage level RTIB of the first node ND1. In an embodiment, as the voltage level RTIB of the first node ND1 increases in the SF corner, the amount of the keeper current Ikeeper may decrease.

For example, the current control circuit 540 may include first to third PMOS transistors P21, P22, and P23. The first PMOS transistor P21 may be coupled between the power supply voltage node and a second node ND2 and have a gate receiving the sensing enable signal SA_ENB. The first PMOS transistor P21 may drive the second node ND2 to the power supply voltage level when the sensing enable signal SA_ENB is activated to a logic low level. The second PMOS transistor P22 may be coupled between the second node ND2 and the sensing node S_ND, and have a gate coupled to the first node ND1. The second PMOS transistor P22 may connect the second node ND2 to the sensing node S_ND depending on the voltage level RTIB of the first node ND1. The third PMOS transistor P23 may be coupled between the second node ND2 and the first node ND1, and have a gate coupled to the sensing node S_ND. The third PMOS transistor P23 may connect the second node ND2 to the first node ND1 depending on the voltage level (i.e., the first data RTI) of the sensing node S_ND. In an embodiment, the first to third PMOS transistors P21, P22, and P23 may be implemented using PMOS transistors having an opposite polarity type to that of the cell transistor.

The sensing circuit 550 may output the second data RDATA to the data line DL by sensing the first data RTI at the sensing node S_ND. The sensing circuit 550 may be implemented with an inverter coupled between the sensing node S_ND and the data line DL. The inverter may be implemented using a PMOS transistor and an NMOS transistor coupled in series between the power supply voltage node and the ground voltage node. The sensing circuit 550 of FIG. 7 may be implemented as an inverter without a feedback inverter (e.g., the second inverter INV2 of FIG. 4), unlike the sensing circuit 340 of FIG. 4.

Hereinafter, with reference to the drawings, an operation of the sense amplifier 442 of FIG. 7 will be described.

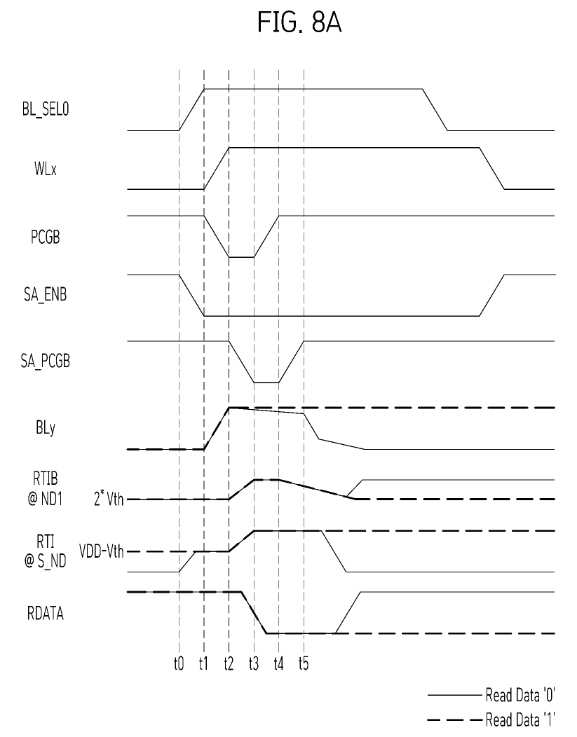

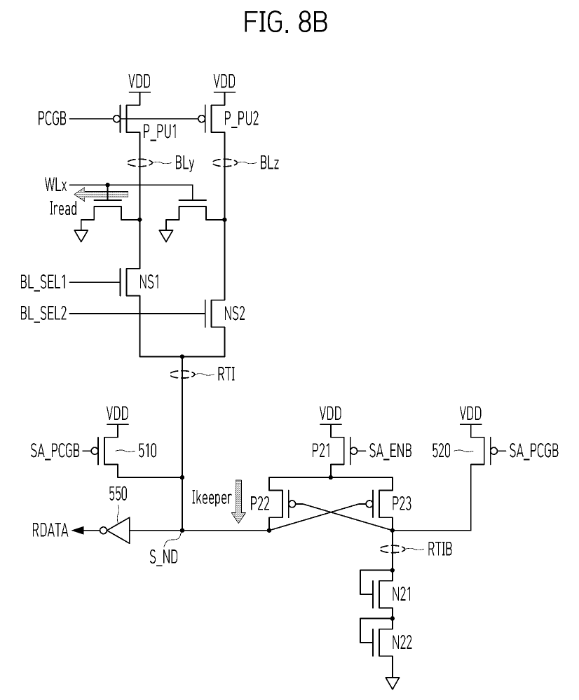

FIGS. 8A and 8B are a timing diagram and a circuit diagram for describing a sensing operation of the sense amplifier 442 of FIG. 7.

Referring to FIG. 8A, prior to time point t0, since the sensing enable signal SA_ENB is deactivated to a logic high level, the first data RTI remains at a logic low level even when the voltage level RTIB of the first node ND1 is at a level of 2×Vth. Accordingly, the sensing circuit 550 may invert the first data RTI of a logic low level to output the second data RDATA of a logic high level to the data line DL.

At time point t0, the first column selection signal BL_SEL0 is activated to a logic high level, and the sensing enable signal SA_ENB is activated to a logic low level. The first connection transistor NS1 connects the first bit line BLy to the column line CL in response to the first column selection signal BL_SEL0, and the first PMOS transistor P21 is turned on to drive the second node ND2 to the power supply voltage node. At this time, since the voltage level RTIB of the first node ND1 remains at 2×Vth, the second PMOS transistor P22 is weakly turned on and allows the keeper current Ikeeper to weakly flow into the sensing node S_ND. Although the voltage level of the sensing node S_ND may increase, it is insufficient to cause a logic inversion. Therefore, the sensing circuit 550 may maintain the second data RDATA at a logic high level.

At time point t1, the precharge signal PCGB is activated to a logic low level, and the word line WLx is activated. The first precharge transistor P_PU1 and the second precharge transistor P_PU2 are activated in response to the precharge signal PCGB, and precharge both the first bit line BLy and the second bit line BLz to the power supply voltage level. In addition, as the word line WLx is selected, a sensing operation for reading data from the first memory cell MC1 may begin. As the first bit line BLy is precharged, the sensing node S_ND may also be precharged to the power supply voltage level. However, since the first connection transistor NS1 is implemented with an NMOS transistor, the sensing node S_ND is charged only up to (VDD − Vth), not fully to the power supply voltage level. As a result, the sensing circuit 550 may maintain second data RDATA at a logic high level.

At time point t2, as the sensing precharge signal SA_PCGB is activated to a logic low level, the first sensing precharge circuit 510 precharges the sensing node S_ND to the power supply voltage level and the second sensing precharge circuit 520 precharges the first node ND1 to the power supply voltage level. When the first memory cell MC1 is not connected to the first bit line Bly, i.e., when the stored data is “1”, the first bit line BLy may maintain the power supply voltage level. In contrast, when the first memory cell MC1 is connected to the first bit line Bly, i.e., when the stored data is “0”, the voltage level of the first bit line BLy may drop from the power supply voltage level. Due to the second sensing precharge circuit 520, the voltage level RTIB of the first node ND1 becomes the power supply voltage level, turning off the second PMOS transistor P22 so that no keeper current Ikeeper flows into the sensing node S_ND. However, the first sensing precharge circuit 510 charges the sensing node S_ND to the power supply voltage level, and at the time when the voltage level of the sensing node S_ND has sufficiently increased, the sensing circuit 550 may output the second data RDATA of a logic low level to the data line DL, by inverting the first data RTI of a logic high level at the sensing node S_ND.

At time point t3, as the precharge signal PCGB is deactivated, the precharge operation on the first bit line BLy is terminated.

At time point t4, as the sensing precharge signal SA_PCGB is deactivated, the precharge operation on the sensing node S_ND and the first node ND1 is terminated. During the deactivation of the sensing precharge signal SA_PCGB, the voltage level RTIB of the first node ND1 becomes 2×Vth.

At time point t5, the voltage level of the first bit line BLy may vary depending on the data stored in the first memory cell MC1. For example, when the data "1" is stored in the first memory cell MC1, the first bit line BLy maintains the power supply voltage level, and accordingly, the first data RTI at the sensing node S_ND remains at a logic high level (dotted line). The sensing circuit 550 may output the second data RDATA of a logic low level to the data line DL, by inverting the first data RTI of a logic high level. That is, the sensing circuit 550 may maintain the second data RDATA at a logic low level. At this time, since the voltage level RTIB of the first node ND1 is 2×Vth, the second PMOS transistor P22 is weakly turned on, allowing the keeper current Ikeeper to weakly flow into the sensing node S_ND. As a result, the keeper current Ikeeper may serve to maintain the voltage level of the sensing node S_ND at the power supply voltage level. In contrast, when the data "0" is stored in the first memory cell MC1, the first bit line BLy is discharged from the power supply voltage to the ground voltage level, and accordingly, the sensing node S_ND is also discharged (solid line). Then, the sensing circuit 550 may output the second data RDATA of a logic high level to the data line DL, by inverting the first data RTI at the sensing node S_ND. At this time, the third PMOS transistor P23 is turned on, such that the voltage level RTIB of the first node ND1 becomes the power supply voltage level, and thus the keeper current Ikeeper no longer flows.

As illustrated in FIG. 8B, when the data "0" is stored, while the voltage level of the sensing node S_ND is discharged from the power supply voltage to the ground voltage level, the third PMOS transistor P23 is turned off and the voltage level RTIB of the first node ND1 may remain at 2×Vth. In this case, the second PMOS transistor P22 may be weakly turned on, allowing the keeper current Ikeeper to weakly flow into the sensing node S_ND, which may conflict with the cell current Iread flowing through the cell transistor. However, in an embodiment of the present disclosure, in an SF (Slow-Fast) corner, the threshold voltage of the active resistors N21 and N22 of the replica circuit 530 increases, thereby increasing the voltage level RTIB of the first node ND1. Therefore, although the cell current Iread flowing through the cell transistor composed of the NMOS transistor may decrease, the keeper current Ikeeper also decreases accordingly, thereby minimizing the read failure caused by a conflict between the cell current Iread and the keeper current Ikeeper.

As described above, in the embodiments of the present disclosure, the sensing operations may be accurately performed regardless of process corners, thereby minimizing the read failure by controlling the keeper current using a replica circuit implemented with active resistors of the same polarity type as that of the cell transistors. Accordingly, the reliability of the memory device may be improved. In addition, it is possible to maximize the layout efficiency by overcoming limitations in using high-resistance wiring materials, which has been restricted due to the conflict between the existing cell current and the keeper current.

Although the above embodiments have been described with an example in which the memory device 100 is implemented as a read-only memory (ROM), the embodiments are not limited thereto. According to embodiments, the memory device 100 may include a programmable ROM (PROM), a one-time programmable (OTP) ROM, an erasable programmable ROM (EPROM), and/or an electrically erasable programmable ROM (EEPROM). Alternatively, the memory device 100 may be a non-volatile memory such as a phase-change RAM (PRAM), a magnetic RAM (MRAM), or a resistive RAM (RRAM).

While the embodiments of the present disclosure have been described with respect to the specific embodiments, it will be apparent to those skilled in the art that various changes and modifications may be made without departing from the spirit and scope of the invention as defined in the following claims. Furthermore, the embodiments may be combined to form additional embodiments.

What is claimed is:

1. A sense amplifying circuit comprising:
a replica circuit including one or more active resistors coupled in series between a ground voltage node and a first node;
a current control circuit configured to supply a keeper current to a sensing node coupled to at least one memory cell when a sensing enable signal is activated, and to control an amount of the keeper current based on a voltage level of the first node; and
a sensing circuit configured to sense and output a voltage at the sensing node.

2. The sense amplifying circuit of claim 1, wherein each of the active resistors includes a diode-connected transistor having the same polarity type as that of a cell transistor included in the memory cell.

3. The sense amplifying circuit of claim 1, wherein the current control circuit includes:
a first transistor coupled between a power supply voltage node and a second node and having a gate receiving the sensing enable signal;
a second transistor coupled between the second node and the sensing node and having a gate coupled to the first node; and
a third transistor coupled between the second node and the first node and having a gate coupled to the sensing node.

4. The sense amplifying circuit of claim 3, wherein the first to third transistors have an opposite polarity type to that of a cell transistor included in the memory cell.

5. The sense amplifying circuit of claim 1, wherein the sensing circuit includes an inverter configured to invert the voltage at the sensing node.

6. The sense amplifying circuit of claim 1, further comprising:
a first sensing precharge transistor coupled between a power supply voltage node and the sensing node and having a gate receiving a sensing precharge signal; and
a second sensing precharge transistor coupled between the power supply voltage node and the first node and having a gate receiving the sensing precharge signal.

7. The sense amplifying circuit of claim 1, wherein the memory cell includes a read-only memory (ROM) cell.

8. A memory device comprising:
a memory cell array having a plurality of memory cells arranged between a plurality of word lines and a plurality of bit lines;
a column control circuit configured to select one of the plurality of bit lines based on a column address and connect the selected bit line to a sensing node; and
a sense amplifying circuit including one or more active resistors, which are coupled in series between a ground voltage node and a first node and configured to simulate characteristics of the memory cells, output read data by sensing a voltage at the sensing node and control an amount of a keeper current supplied to the sensing node based on a voltage level of the first node.

9. The memory device of claim 8, wherein the memory cells include read-only memory (ROM) cells.

10. The memory device of claim 8, wherein each of the memory cells include:
a cell transistor coupled between the ground voltage node and a corresponding bit line, and having a gate coupled to a corresponding word line.

11. The memory device of claim 10, wherein each of the active resistors includes a diode-connected transistor having the same polarity type as that of the cell transistor.

12. The memory device of claim 8, wherein the sense amplifying circuit includes:
a replica circuit including the one or more active resistors to simulate characteristics of a cell transistor included in each of the memory cells;
a current control circuit configured to control the amount of the keeper current supplied to the sensing node based on the voltage level of the first node when a sensing enable signal is activated; and
a sensing circuit configured to output the read data by sensing the voltage at the sensing node.

13. The memory device of claim 12, wherein the current control circuit includes:
a first transistor coupled between a power supply voltage node and a second node and having a gate receiving the sensing enable signal;
a second transistor coupled between the second node and the sensing node and having a gate coupled to the first node; and
a third transistor coupled between the second node and the first node and having a gate coupled to the sensing node.

14. The memory device of claim 13, wherein the first to third transistors have an opposite polarity type to that of the cell transistor.

15. The memory device of claim 12, wherein the sensing circuit includes an inverter configured to invert the voltage at the sensing node.

16. The memory device of claim 12, wherein the sense amplifying circuit further includes:
a first sensing precharge transistor coupled between a power supply voltage node and the sensing node and having a gate receiving a sensing precharge signal; and
a second sensing precharge transistor coupled between the power supply voltage node and the first node and having a gate receiving the sensing precharge signal.
